(19) United States
(12) Patent Application Publication
(10) Pub. No.: US 2018/0079640 A1
(43) Pub. Date: Mar. 22, 2018

(54) MEMS DEVICE WITH OFFSET ELECTRODE

(71) Applicant: Innovative Micro Technology, Goleta, CA (US)

(72) Inventors: Christopher S. GUDEMAN, Lompoc, CA (US); Marin Sigurdson, Goleta, CA (US)

(73) Assignee: Innovative Micro Technology, Goleta, CA (US)

(21) Appl. No.: 15/700,179

(22) Filed: Sep. 11, 2017

Related U.S. Application Data
(60) Provisional application No. 62/397,978, filed on Sep. 22, 2016.

(51) Int. Cl. B81B 3/00; B81B 7/00; B81C 1/00

(52) U.S. Cl. CPC B81B 3/0013; B81B 7/008; B81C 1/00206; B81B 3/0086; B81B 7/0006; B81C 1/00936

(57) ABSTRACT

Systems and methods for forming an electrostatic MEMS switch that is used to switch a source of current or voltage. At least one surface of the MEMS switch may be rotated on approach to another substrate, such that when the surfaces are separated, the forces are shearing forces rather than static frictional forces.

### CROSS REFERENCE TO RELATED APPLICATIONS

This US non-Provisional US patent application claims priority to U.S. Provisional Patent Application Ser. No. 62/397,978, filed Sep. 22, 2016, which is incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a microelectromechanical systems (MEMS) switch device, and its method of manufacture. More particularly, this invention relates to a MEMS switch, which closes contacts to activate a circuit.

Microelectromechanical systems are devices often having moveable components which are manufactured using lithographic fabrication processes developed for producing semiconductor electronic devices. Because the manufacturing processes are lithographic, MEMS devices may be made in very small sizes, and in large quantities. MEMS techniques have been used to manufacture a wide variety of sensors and actuators, such as accelerometers and electrostatic cantilevers.

MEMS techniques have also been used to manufacture electrical relays or switches of small size, often using an electrostatic actuation means to activate the switch. MEMS devices often make use of silicon-on-insulator (SOI) wafers, which are a relatively thick silicon “handle” wafer with a thin silicon dioxide insulating layer, followed by a relatively thin silicon “device” layer. In the MEMS devices, a thin cantilevered beam of silicon may be etched into the silicon device layer, and a cavity is created adjacent to the thin beam, typically by etching the thin silicon dioxide layer below it to allow for the electrostatic deflection of the beam. Electrodes provided above or below the beam may provide the voltage potential which produces the attractive (or repulsive) force to the cantilevered beam, causing it to deflect within the cavity.

One known embodiment of such an electrostatic relay is disclosed in U.S. Pat. No. 6,486,425 to Seki. The electrostatic relay described in this patent includes a fixed substrate having a fixed terminal on its upper surface and a moveable substrate having a moveable terminal on its lower surface. Upon applying a voltage between the moveable electrode and the fixed electrode, the moveable substrate is attracted to the fixed substrate such that an electrode provided on the moveable substrate contacts another electrode provided on the fixed substrate to close the microrelay.

MEMS devices that contain surfaces that come into contact with one another, such as the switch described above, are fraught with stiction, the unwanted adhesion of these surfaces through the formation of covalent chemical bonds. In the case of metal surfaces that come into contact, as is the case of ohmic electrical switches, welding of these surface is a very common failure mechanism. In the case of MEMS devices, this problem is further increased because very small forces are available to separate the two surfaces.

Prior art approaches to the stiction problem include: 1) Rough surfaces. These provide for minimal true area of contact, thus minimizing the area of stiction/welding. However, switch contact resistance increases as the true area of contact is decreased, thus adversely affecting the switch performance. Also, the roughness of surfaces is typically difficult to control. 2) Stronger restoring force springs. This provides for a higher separation force. However, this avenue is limited in the case of MEMS devices, because of their small size, and consequently small forces available.

Accordingly, for small, fragile MEMS devices, a new approach is needed that reduces stiction.

### SUMMARY

A novel approach to the stiction problem may be the peeling apart of two surfaces to separate them. This allows for the welded areas to be separated incrementally, thus requiring less force. This requires flexible surfaces, which are generally fragile. A similar approach is to use shearing forces. The shear strength of materials is generally less than the tensile strength. If the welded surfaces can be translated in a direction parallel to the surface, less force is required to break the weld. The systems and methods described here use shearing forces to break the adhesion, or welding, between the surfaces.

We describe a method that uses an offset arrangement of a movable electrode relative to an electrode fixed to a substrate, to rotate the electrode as it moves. Because of the shape of the electrostatic field lines between the offset shapes, a torque may arise around an axis normal to the movable electrode. Accordingly, when the movable electrode or contact surface approaches a fixed electrode or contact surface, the movable electrode may rotate about an axis substantially orthogonal to the electrode contact surfaces. Because of the attachment configuration of the movable electrode to the substrate, a torsional restoring force may also arise. This restoring force and rotation may reduce the force necessary to separate two surfaces in contact.

In other words, because of the offset arrangement, the surfaces may be peeled apart rather than simply separated by a restoring force. The peeling may significantly reduce the forces necessary to separate the surfaces.

These concepts are illustrated and discussed conceptually in FIGS. 1 and 2, and a detailed embodiment is illustrated and discussed with respect to FIGS. 3 and 4.

Accordingly, a MEMS device is disclosed, which comprises a plurality of contact surfaces including a movable surface and a surface fixed to a substrate, wherein the movable surface is rotated with respect to the fixed surface in the quiescent (unactuated, or as manufactured) position, such that electrostatic forces between the movable surface and the fixed surface impart a rotational motion to the movable surface with respect to the fixed surface, and wherein the rotational motion occurs substantially around an axis orthogonal to the substrate.

These and other features and advantages are described in, or are apparent from, the following detailed description.

### BRIEF DESCRIPTION OF THE DRAWINGS

Various exemplary details are described with reference to the accompanying drawings, which however, should not be taken to limit the invention to the specific embodiments shown but are for explanation and understanding only.

FIG. 1 is an illustrative exemplary plan view of an exemplary offset arrangement for a MEMS device.

FIG. 2 is an illustrative exemplary plan view of an exemplary offset arrangement for a MEMS device, showing exemplary dimensions.

FIG. 3 is a cross sectional view of an exemplary embodiment for an offset MEMS device; and

FIG. 4 is an exemplary plan view of the exemplary embodiment of the offset MEMS device.

It should be understood that the drawing is not necessarily to scale, and that like numbers maybe may refer to like features.

### DETAILED DESCRIPTION

The approach described here is directed to reducing the stiction, or welding adhesion that must be overcome to separate the surfaces. The shear strength of materials is generally less than the tensile strength. If the welded or adhered surfaces can be translated in a direction parallel to the surface, less force is required to break the weld. The systems and methods described here use torsional shearing forces to reduce the overall force needed to separate the surfaces and break the adhesion between the surfaces.

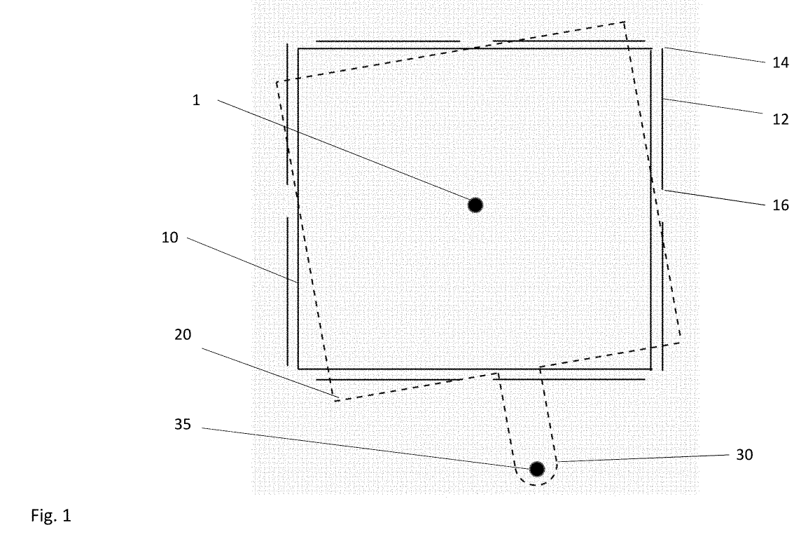

In the system and method described here, a MEMS switch with an offset electrode is described. The surfaces of an electrostatically actuated device may be rotationally offset from one electrode with respect to the other, as shown conceptually in FIG. 1. This method provides a means of pulling the two surfaces into contact while preloading the restoring force springs such that they will provide a torsional force on one of the plates when the electrostatic field is removed.

Referring to FIG. 1, 10 is a movable suspended plate electrode which is able to rotate about an axis 1 normal to its surface, and 20 is a fixed adjacent electrode. 10 and 20 are rotated with respect to one another in the as-manufactured position. A voltage differential may be applied between the movable suspended electrode 10 and the rotated fixed electrode 20, in order to draw them together electrostatically and close the switch.

The rotated fixed adjacent electrode 20 may include a pad deposited on the surface of a substrate in this rotated orientation. 30 may be an electrical tab in electrical communication with a feed through or through silicon via (TSV) 35 and with the rotated, fixed electrode 20. A signal or a voltage may be applied to the pad through the tab 30 and via 35 to the rotated fixed electrode 20. Accordingly, in one embodiment, the voltage differential may be applied to the rotated fixed adjacent electrode 20 relative to the suspended movable plate 10, by the tab and via 35. The movable suspended plate may be held at another voltage by electrical coupling to the substrate, for example.

The movable suspended plate electrode 10 may be suspended above the fixed adjacent electrode 20 and tab 30. Movable, suspended plate electrode 10 may be rotated with respect to fixed electrode 20. Because of this geometry, the field lines emanating from one electrode and ending on the other will curve in space, and apply a torque to movable, suspended plate electrode 10. As a result of this torque, suspended electrode 10 may rotate as it approaches fixed electrode 20.

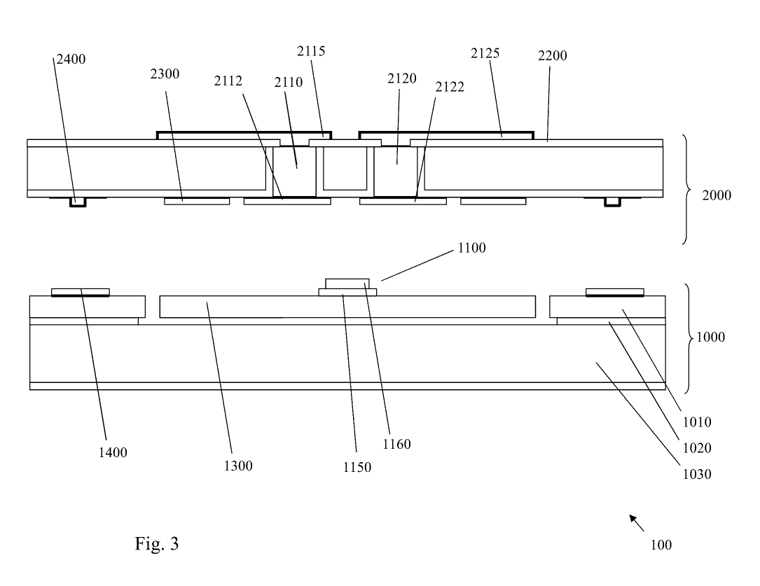

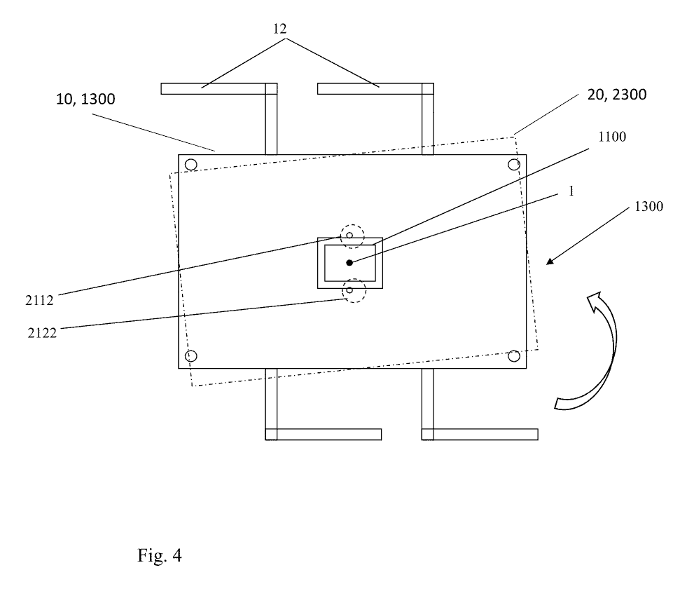

To accommodate this rotation, the attachment points to movable, suspended plate electrode 10 may be configured as shown schematically in FIG. 1. Springs 12 may attach the movable, suspended plate electrode 10 over the pad, wherein the corners 14 of the springs may be attached to the corner of the movable, suspended plate electrode 10, and 16 may be attached to the movable, suspended plate electrode 10 at an intermediate point on the side of the movable, suspended plate electrode 10. These springs may apply a torsional restoring force which opens the switch by rotating the movable electrode about an axis 1 normal to its surface. Accordingly, the movable electrode may rotate in one sense on closing, and rotate in the opposite sense on opening to its initial condition. These concepts are illustrated in detail with respect to the embodiment shown in FIGS. 3 and 4.

Device Design

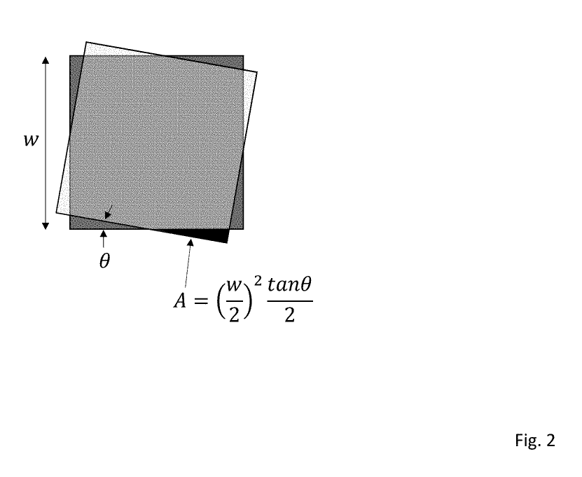

Design parameters are illustrated in FIG. 2. In FIG. 2, the following parameters are illustrated for a square plate of dimension w:
T=torque
E=energy
V=voltage
C=capacitance
W=width of plate
d=separation of plates
θ=relative rotation angle

The functional dependence of these quantities on one another may be stated as:

$$T = \frac{\partial E}{\partial θ} \qquad ( 1 )$$

That is, torque is the incremental change in energy per incremental change in relative rotation angle θ. From electrostatics, there is the well known relationship between voltage, capacitance and energy.

E=½CV² (2)

Where capacitance, C, is given by:

$$C = \frac{{ϵϵ}_{o} A}{d} \qquad ( 3 )$$

Generally speaking, the area of the polygon shown in FIG. 2 is given by

$$A = {( \frac{w}{2} )}^{2} \frac{tan θ}{2} \qquad ( 4 )$$

As a result, the change in effective area depends on the relative rotation angle θ according to

$$A = {A}_{o} - \frac{8 {w}^{2} tan θ}{8} \qquad ( 5 )$$

where A₀ is the nominal (unrotated) plate area. Accordingly, the functional dependence of energy on changes in the relative rotation angle θ is given by

$$\frac{\partial E}{\partial θ} = \frac{{ϵϵ}_{o} ( {w}^{2} {sec}^{2} θ ) {V}^{2}}{2 d} \qquad ( 6 )$$

In the limit θ<<1, this becomes

$$\frac{\partial E}{\partial θ} = T = \frac{{ϵϵ}_{o} {w}^{2} {V}^{2}}{2 d} \qquad ( 7 )$$

As can be seen in equations (1)-(7), the energy stored torsionally in the device is related to its size (w), inversely related to the distance d between the plates, and to the square of the voltage between them. It also varies as the square of the characteristic dimension, w. As would be logically expected, the torsional force climbs rapidly with voltage and size, and as the inverse of the distance d between the plates. Accordingly, the mount of stiction expected in these MEMS devices may inform the selection of voltage and gap for the structure.

### Exemplary Embodiments

FIG. 3 is a cross sectional view of an embodiment of the MEMS electrostatic switch device with an offset electrode 100. This embodiment may be fabricated on two substrates, a plate substrate 1000 on which the movable plate 1300 is formed, and a via substrate 2000, on which fixed contacts 2112 and 2122 are formed. Accordingly, in this embodiment, the movable surface 10 may be a movable suspended plate 1300 attached to one substrate 1000 and fixed surface 20 may be the fixed electrode 2300 attached to the second substrate 2000. As mentioned, the movable plate 1300 may be rotated with respect to fixed plate 2300 in the as manufactured (quiescent or unactuated) position. The plate substrate 1000 may be an SOI wafer, and the via substrate 2000 may be a silicon wafer, for example. The SOI plate substrate 1000 may include a silicon device layer 1010, an insulating layer 1020, and a thicker, silicon handle layer 1030. SOI wafers are well known in the art.

The electrostatic MEMS switch with offset electrode 100 may include a plate 1300 bearing at least one shunt bar 1100. The shunt bar 1100 may be dimensioned to span the fixed contact 2112 and 2122 when the shunt bar 1100 is laid across the fixed contacts 2112 and 2122 as a result of activation of the switch. The shunt bar 1100 may include an insulating pad 1150 to isolate the shunt bar 1100 from the rest of the substrate 1000. The shunt bar may also have an electrical contact surface 1160. The movable plate 1300 may be deformable, meaning that it is sufficiently thin compared to its length or its width to be deflected when a force is applied, and may vibrate in response to an impact. The movable plate 1300 may be suspended above the silicon handle layer 1030 of an SOI plate substrate 1000 by a plurality of spring beams (not shown in the cross section of FIG. 3, but shown in the plan view of FIG. 4), which are themselves affixed to the silicon handle layer 1030 by anchor points formed from the insulating dielectric layer 1020 of the SOI plate substrate 1000. As used herein, the term “spring beam” should be understood to mean a beam of flexible material affixed to a substrate at a proximal end, and formed in substantially one plane, but configured to move and provide a restoring force in a direction substantially perpendicular to that plane. The movable plate 1300 may carry at least one conductive shunt bar 1100 which operates to close the switch 100, as described below.

Additional details of such a device are disclosed in U.S. Pat. No. 7,893,798 B2, issued Feb. 22, 2011 and assigned to the same assignee. This patent is incorporated by reference in its entirety.

The movable plate 1300 may be actuated electrostatically by an adjacent electrostatic electrode 2300, which may be disposed directly above (or below) the movable plate 1300, and may be fabricated on the via substrate 2000. The movable plate 1300 itself may form one plate of a parallel plate capacitor, with the electrostatic electrode 2300 forming the other plate. Despite the terminology of “parallel plate”, it should be understood the movable electrode may be rotationally offset with respect to the fixed electrode.

When a differential voltage is placed on the movable plate 1300 relative to the adjacent electrostatic electrode 2300, field lines emanating from the electrodes may be twisted in space, applying a torsional electrostatic force to the movable plate 1300. The plate 1300 may thus rotate as it approaches the adjacent electrode 2300.

In any event, the movable plate 1300 is drawn toward the adjacent electrostatic electrode 2300. The action raises (or lowers) the shunt bar 1100 until it spans the contact points 2112 and 2122, thereby closing an electrical circuit. Although the embodiment illustrated in FIG. 3 shows the plate formed on the lower substrate and the vias and contacts formed on the upper substrate, it should be understood that the designation “upper” and “lower” is arbitrary. The movable plate may be formed on either the upper substrate or lower substrate, and the vias and contacts formed on the other substrate. However, for the purposes of the description which follows, the embodiment shown in FIG. 3 is presented as an example, wherein the plate is formed on the lower substrate and is pulled upward by the adjacent electrode formed on the upper substrate.

The minimum separation between the substrates 1000 and 2000 may be defined by hard standoffs 2400 within the bondline. These standoffs may be made of a material with sufficient mechanical competency to serve as a hard stop between the substrates, especially during the higher temperature bonding process when the plate substrate 1000 is bonded to the via substrate 2000.

When the switch is opened, because of the configuration of the restoring springs 12, the movable plate 1300 may twist rotationally upon opening. This rotational movement may reduce the force required to open the switch 100, because it includes a shear force rather than just a normal force.

FIG. 4 is a plan view of the MEMS device with an offset electrode 100. The movable plate 1300 shown in FIG. 4 may correspond to the suspended electrode 10 in FIG. 1. The fixed adjacent electrode 2300 in FIG. 4 may correspond to the fixed electrode 20 in FIGS. 1 and 2. When a differential voltage is placed on the movable plate 1300 relative to the adjacent electrostatic electrode 2300, the movable plate is drawn toward the adjacent electrostatic electrode 2300. The action raises (or lowers) the shunt bar 1100 until it spans the contact points 2112 and 2122, thereby closing an electrical circuit. Because of the configuration of the offset electrodes 1300 and 2300, and restoring springs 12 shown in FIG. 4, the movable plate 1300 may rotate as it approaches fixed plate 2300, because of the torque exerted by the field around the orthogonal axis. The movable plate 1300 may rotate at least about 0.1-5 milli-degrees relative to the fixed electrode 2300 as it approaches the fixed electrode. The rotation may be in one sense as the electrodes approach one another (CW for example) and in the opposite sense (CCW for example) as they separate.

The configuration of restoring springs 12 shown in FIG. 4 is exemplary only, and it should be understood that other configurations are anticipated as well. There may be, for example, other symmetry axes in addition to the horizontal symmetry axis of FIG. 4. For example, by altering the shapes of the sprint 12, there may be another vertical symmetry axis, or other numbers of springs and shapes. However, in any case, the spring may be configured to exert a torsional force on the movable plate 1300.

It should be understood that the electrodes or plates may be of any arbitrary shape, such as squares, rectangle or any other polygon. The device may therefore define a parallel plate capacitor employing plates of similar polygons wherein one plate is rotated about the axis 1 normal to the plane of the plates such that edges of the plates are not parallel.

Fabrication

The MEMS device with offset electrode may be fabricated as follows. Beginning with the plate substrate 1000, an insulating layer of dielectric material 1020, such as SiO₂ may be grown or deposited on the silicon surfaces. Alternatively, the SiO₂ layer may exist as the insulating layer 1020 on a silicon-on-insulator (SOI) substrate 1000. The dielectric layer 1020 may then be etched away beneath and around the movable plate 1300, using a hydrofluoric acid liquid etchant, for example. The liquid etch may remove the silicon dioxide dielectric layer 1020 in all areas where the movable plate 1300 is to be formed. The liquid etch may be timed, to avoid etching areas that are required to affix the spring beams of the movable plate 1300, which will be formed later, to the handle layer 1030. Additional details as to the dry and liquid etching procedure used in this method may be found in U.S. patent application Ser. No. 11/359,558 (Attorney Docket No. IMT-SOI Release), filed Feb. 23, 2006, now U.S. Pat. No. 7,785,913 issued Aug. 13, 2010 and incorporated by reference in its entirety.

The next step in the exemplary method is the formation of the dielectric pad 1150 as depicted in FIG. 4. Pad structures 1150 forms an electrical isolation barrier between the shunt bar 1100 and the movable plate 1300, and other standoffs may form a dielectric barrier preventing the corners of the movable plate 1300 from touching the adjacent actuation electrode 2300. The movable plate 1300 and adjacent actuation electrode 2300 form the two plates of a parallel plate capacitor, such that a force exists between the plates when a differential voltage is applied to them, drawing the movable plate 1300 towards the adjacent actuation electrode 2300.

The dielectric structure 1150 may be silicon dioxide, which may be sputter-deposited over the surface of the device layer 1010 of the SOI plate substrate 1000. The silicon dioxide layer may be deposited to a depth of, for example, about 300 nm. The 300 nm layer of silicon dioxide may then be covered with photoresist which is then patterned. The silicon dioxide layer is then etched to form insulating structure 1150. The photoresist is then removed from the surface of the device layer 1010 of the SOI plate substrate 1000. Because the photoresist patterning techniques are well known in the art, they are not explicitly depicted or described in further detail.

In the next step, a conductive material is deposited and patterned to form the shunt bar 1100 and a portion of what may form the hermetic seal. The hermetic seal may include a metal alloy formed from melting a first metal into a second metal, and forming an alloy of the two metals which blocks the transmission of gases. In preparation of forming the hermetic seal, a perimeter of the first metal material 1400 may be formed around the movable plate 1300. The conductive material may actually be a multilayer comprising first a thin layer of chromium (Cr) for adhesion to the silicon and/or silicon dioxide surfaces. The Cr layer may be from about 5 nm to about 20 nm in thickness. The Cr layer may be followed by a thicker layer about 300 nm to about 700 nm of gold (Au), as the conductive metallization layer. Preferably, the Cr layer is about 15 nm thick, and the gold layer is about 600 nm thick. Another thin layer of molybdenum may also be used between the chromium and the gold to prevent diffusion of the chromium into the gold, which might otherwise raise the resistivity of the gold.

Each of the Cr and Au layers may be sputter-deposited using, for example, an ion beam deposition chamber (IBD). The conductive material may be deposited in the region corresponding to the shunt bar 1100, and also the regions which will correspond to the bond line 1400 between the plate substrate 1000 and the via substrate 2000 of the dual substrate electrostatic MEMS plate switch with offset electrode 100. This bond line area 1400 of metallization will form, along with a layer of indium, a seal which will hermetically seal the plate substrate 1000 with the via substrate 2000, as will be described further below.

While a Cr/Au multilayer is disclosed as being usable for the metallization layer of the shunt bar 1100, it should be understood that this multilayer is exemplary only, and that any other choice of conductive materials or multilayers having suitable electronic transport properties may be used in place of the Cr/Au multilayer disclosed here. For example, other materials, such as titanium (Ti) may be used as an adhesion layer between the Si and the Au. Other exotic materials, such as ruthenium (Ru) or palladium (Pd) can be deposited on top of the Au to improve the switch contact properties, etc. However, the choice described above may be advantageous in that it can also participate in the sealing of the device through the alloy bond, as will be described more fully below.

To form the movable plate 1300 and restoring springs 12, the surface of the device layer 1010 of the SOI plate substrate 1000 is covered with photoresist which is patterned with the design of the movable plate and springs 12. The movable plate outline is the etched into the surface of the device layer by, for example, deep reactive ion etching (DRIE). Since the underlying dielectric layer 1020 has already been etched away, there are no stiction issues arising from the liquid etchant, and the movable plate is free to move upon its formation by DRIE. As before, since the photoresist deposition and patterning techniques are well known, they are not further described here.

Turning now to the via substrate 2000, another metallization region may be deposited over the substrate 2000, as shown in FIG. 3. This metallization layer may form the bond ring 2400 as well as adjacent electrostatic electrode 2300. The metallization region may also define the second plate 2300 of the parallel plate capacitor of the switch 100. In one exemplary embodiment, the metallization layer may actually be a multilayer of Cr/Au, the same multilayer as was used for the metallization layer 1400 on the plate substrate 1000 of the dual substrate electrostatic MEMS plate switch with offset electrode 100. The metallization multilayer may have similar thicknesses and may be deposited using a similar process as that used to deposit metallization layer 1400 on substrate 1000. The metallization layer may also serve as a seed layer for the deposition of a metal solder bonding material, as described in the incorporated '798 patent. Layer 2200 may be a native insulating layer of SiO₂ that forms around the silicon substrate 2000. Two more external (to the switch) electrical pads 2115 and 2125 may be connected to through substrate vias 2110 and 2120 (TSV) may provide electrical access to the two electrical nodes 2112 and 2122 within the device 100.

Each of the Cr and Au layers may be sputter-deposited using, for example, an ion beam deposition chamber (IBD). The conductive material may be deposited in the region corresponding to the adjacent fixed actuation electrode 2300, and also the regions which will correspond to the bond line 2400 between the plate substrate 1000 and the via substrate 2000 of the dual substrate electrostatic MEMS plate switch with offset electrode 100. This bond line area 1400 and 2400 of metallization may form, along with a layer of indium, a seal which will hermetically seal the plate substrate 1000 with the via substrate 2000. Alternatively, a thermocompression bonding technique may make use of two gold layers 1400 and 2400.

Finally, to form the switch, SOI plate substrate 1000 is pressed against the via substrate 2000 and the substrates are bonded together in a wafer bonding chamber for example. The adhesive may be the previously mentioned thermocompression bond, metal alloy bond, or a glass frit bond for example. At bonding, the substrate-to-substrate separation may be determined by a standoff 2400 in the bondline, as shown in the FIG. 3.

Accordingly, a MEMS device is described, which may include a plurality of contact surfaces including a movable surface and a surface fixed to a substrate, wherein the movable surface is rotated with respect to the fixed surface in a quiescent position, such that electrostatic forces between the movable surface and the fixed surface impart a rotational motion to the movable surface with respect to the fixed surface when actuated, and wherein the rotational motion occurs substantially around an axis 1 orthogonal to the substrate. The offset springs may be attached to movable surface which impart a rotational restoring force. The rotational motion may be at least 0.1 to 5 milli-degrees about an axis 1 orthogonal to the fixed surface. The movable and fixed surfaces may be of at least one of gold (Au), RuO₂, a gold/nickel alloy, palladium (Pd), silver (Ag), tungsten (W) and platinum (Pt).

The MEMS device may be a switch that closes two contact surfaces with a voltage differential between the two surfaces.

The MEMS device may further include a MEMS switch formed with two substrates, with at least one contact surface on each substrate, wherein the switch is formed when the two substrates are bonded together. The MEMS switch may be electrostatically actuated. When the MEMS switch is electrostatically actuated, a shunt bar on one substrate may span two contacts on the other substrate, thereby closing the switch. The contact surface may be the surface of a conductive pad, and may move rotationally towards a fixed electrical pad upon application of a voltage between the two contact surfaces.

A method for method of making a MEMS device is also disclosed. The method may include forming a plurality of contact surfaces including a movable surface and a surface fixed to a plane of a substrate, wherein the movable surface is rotated with respect to the fixed surface in the quiescent position, wherein the electrostatic field between the fixed surface and the movable surface imparts a rotational motion to the movable surface with respect to the fixed surface, and wherein the rotational motion occurs substantially around an axis 1 orthogonal to the plane of the substrate when the device is actuated.

Within the method, the offset springs may be attached to the movable surface which impart a rotational restoring force to the movable surface. The electrostatic forces may cause a rotation of at least 0.1 to 5 milli-degrees of the movable with respect to the fixed surface about an axis 1 orthogonal to the fixed surface as the movable surface approaches the fixed surface. The movable and fixed surfaces may be of at least one of gold (Au), RuO₂, a gold/nickel alloy, palladium (Pd), silver (Ag), tungsten (W) and platinum (Pt).

The method may further include forming at least one through substrate via that provides external electrical access to at least one of the movable and fixed surfaces. I may also include forming the MEMS device and the contact surface on a device substrate, forming a device cavity in a lid wafer, and enclosing the device and the contact surface in the device cavity by bonding the lid substrate to the device substrate.

Fabricating the switch may include forming a movable plate on one substrate and at least one via on a second substrate, and forming the switch by bonding the first substrate to the second substrate. The MEMS switch may be electrostatically actuated. When the MEMS switch is electrostatically actuated, a shunt bar on one substrate may span two contact surfaces on the other substrate, thereby closing the switch.

The MEMS device in alternative may include a parallel plate capacitor employing plates of similar polygons wherein one plate is rotated about the axis normal to the plane of the plates such that the edges of the plates are not parallel. In this device, one of the plates may be mounted on springs that allow it to move in a direction parallel to the axis. When a voltage difference is applied between the plates, the plates may be drawn together.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, while the disclosure describes a number of fabrication steps and exemplary thicknesses for the layers included in the MEMS switch, it should be understood that these details are exemplary only, and that the systems and methods disclosed here may be applied to any number of alternative MEMS or non-MEMS devices. Furthermore, although the embodiment described herein pertains primarily to an electrical switch, it should be understood that various other devices may be used with the systems and methods described herein, including actuators and valves, for example. Accordingly, the exemplary implementations set forth above, are intended to be illustrative, not limiting.

What is claimed is:

1. A MEMS device, comprising:
a plurality of contact surfaces including a movable surface and a surface fixed to a substrate, wherein the movable surface is rotated with respect to the fixed surface in a quiescent position, such that electrostatic forces between the movable surface and the fixed surface impart a rotational motion to the movable surface with respect to the fixed surface when actuated, and wherein the rotational motion occurs substantially around an axis orthogonal to the substrate.

2. The MEMS device of claim 1, wherein offset springs are attached to movable surface which impart a rotational restoring force.

3. The MEMS device of claim 1, wherein rotational motion is at least 0.1 to 5 milli-degrees about an axis orthogonal to the fixed surface.

4. The MEMS device of claim 1, wherein the movable and fixed surfaces comprise at least one of gold (Au), RuO₂, a gold/nickel alloy, palladium (Pd), silver (Ag), tungsten (W) and platinum (Pt).

5. The MEMS device of claim 1, wherein the MEMS device is a switch that closes two contact surfaces with a voltage differential between the two surfaces.

6. The MEMS device of claim 1, wherein the MEMS device further comprises a MEMS switch formed with two substrates, with at least one contact surface on each substrate, wherein the switch is formed when the two substrates are bonded together.

7. The MEMS device of claim 6, wherein the MEMS switch is electrostatically actuated.

8. The MEMS device of claim 6, wherein when the MEMS switch is electrostatically actuated, a shunt bar on one substrate spans two contacts on the other substrate, thereby closing the switch.

9. The MEMS device of claim 6, wherein the contact surface is the surface of a conductive pad, and moves rotationally towards a fixed electrical pad upon application of a voltage between the two contact surfaces.

10. A method of making a MEMS device, comprising:
forming a plurality of contact surfaces including a movable surface and a surface fixed to a plane of a substrate, wherein the movable surface is rotated with respect to the fixed surface in the quiescent position, wherein the electrostatic field between the fixed surface and the movable surface imparts a rotational motion to the movable surface with respect to the fixed surface, and wherein the rotational motion occurs substantially around an axis orthogonal to the plane of the substrate when the device is actuated.

11. The MEMS device of claim 10, wherein offset springs are attached to the movable surface which impart a rotational restoring force to the movable surface.

12. The MEMS device of claim 10, wherein the electrostatic forces cause a rotation of at least 0.1 to 5 milli-degrees of the movable with respect to the fixed surface about an axis orthogonal to the fixed surface as the movable surface approaches the fixed surface.

13. The MEMS device of claim 10, wherein the movable and fixed surfaces comprise at least one of gold (Au), RuO₂, a gold/nickel alloy, palladium (Pd), silver (Ag) and platinum (Pt).

14. The method of claim 10, further comprising:
forming at least one through substrate via that provides external electrical access to at least one of the movable and fixed surfaces.

15. The method of claim 10, further comprising:
forming the MEMS device and the contact surface on a device substrate;
forming a device cavity in a lid wafer; and
enclosing the device and the contact surface in the device cavity by bonding the lid substrate to the device substrate.

16. The method of claim 13, wherein fabricating a switch comprises:
forming a movable plate on one substrate and at least one via on a second substrate;
forming the switch by bonding the first substrate to the second substrate

17. The MEMS device of claim 7, wherein when the MEMS switch is electrostatically actuated, a shunt bar on one substrate spans two contact surfaces on the other substrate, thereby closing the switch.

18. A MEMS device comprising:
a parallel plate capacitor employing plates of similar polygons wherein one plate is rotated about the axis normal to the plane of the plates such that the edges of the plates are not parallel.

19. The device of claim 18, wherein one of the plates is mounted on springs that allow it to move in a direction parallel to the axis.

20. The device of claim 19, wherein a voltage difference is applied between the plates, which induces them to be drawn together.
